(19) United States
(12) Patent Application Publication
(10) Pub. No.: US 2008/0122058 A1
(43) Pub. Date: May 29, 2008

(54) Partially stacked semiconductor devices

(76) Inventor: Masahiro Inohara, Fujisawa (JP)

Correspondence Address: SPRINKLE IP LAW GROUP, 1301 W. 25TH STREET, SUITE 408, AUSTIN, TX, 78705, US

(21) Appl. No.: 11/516,974

(22) Filed: Sep. 7, 2006

(51) Int. Cl. H01L 23/02; H01L 21/02

(52) U.S. Cl. 257/686; 438/109; 257/E23.172; 257/E21.002

(57) ABSTRACT

Embodiments of the present invention provide partially stacked semiconductor devices and methods of making the same. In one embodiment, a first LSI chip is strategically buried or embedded in a second LSI chip. One embodiment of a method of making a partially stacked semiconductor device may comprise digging a trench on an area of a diced LSI chip where upper metal interconnects do not exist, placing a known good die in the trench, and applying a coating insulator material to fix the position of the embedded chip. The latter two steps may be repeated. The inter-chip connection between the partially stacked LSI chips can be fabricated by forming through holes connecting the chips and filling the through holes with metal.

### FIELD OF THE INVENTION

This invention relates generally to semiconductor devices. More particularly, embodiments of the present invention relate to partially stacked semiconductor devices and methods of making the same.

### BACKGROUND OF THE INVENTION

Semiconductor manufacturing processes generally involve three stages: crystal wafer growth and preparation, wafer fabrication, and final assembly. The last stage has to do with assembling and packaging the fabricated wafer for final product. During this stage, semiconductor chips may undergo several operations or processes. The order and number of processes can vary, depending upon the package type and other known factors. Semiconductor assembly and packing processes may include separating and sorting the fabricated wafers, mounting and bonding the wafers to appropriate support media (e.g., a circuit board), electrically interconnecting the semiconductor in the package, and preparation the final package.

In some cases, particularly in large scale integration (LSI), not all device components can be placed on a single chip. To overcome the die size limitation, several integrated circuit (IC) chips may be assembled and packaged separately and then mounted onto a circuit board. This conventional technique has several drawbacks, including the low footprint efficiency on the circuit board and the long connection path between LSI chips. Two techniques are known to address this issue. They are shown in FIG. 1 and FIG. 2.

The first technique involves fabricating IC chips separately (Step 110), stacking several diced LSI chips (e.g., chips 101, 102, 103) in a package (Step 120), and connecting the stacked chips 101, 102, 103 via wire bonding 105 (Step 130) to produce a final product 100.

The second technique involves fabricating wafers separately (Step 210), stacking several wafers (e.g., wafers 201, 202, 203) in a package (Step 220), and forming metal plugs 206 for inter-chip connection (Step 230) to produce a final product 200. The stacked and connected wafers are then diced to spec.

These two prior techniques also have several drawbacks.

For example, as shown in FIG. 1, the connection path between LSI chips is longer than the connection path between devices existing in the same chip. Furthermore, the number of connections between LSI chips is limited by the wire bonding pad density. The connection path is shortened in FIG. 2. However, due to wafer-wafer bonding, known good die (KGD) cannot be selected separately.

Moreover, since all stacked dies have to be same size, the area efficiency is decreased.

A need exists for stacked semiconductor devices and methods of making the same without the aforementioned drawbacks of prior techniques. Embodiments of the present invention can address this need and more.

### SUMMARY OF THE INVENTION

Embodiments of the present invention provide partially stacked semiconductor devices and methods of making the same. Embodiments of the present invention advantageously utilize what previously thought to be unusable areas between LSI chips.

In one embodiment, one or more LSI chips are strategically buried or embedded in another LSI chip. For example, high performance LSI typically uses about ten metal interconnect layers and memories such as static random access memory (SRAM) and dynamic RAM (DRAM) may use only the first three or four metal interconnect layers. One embodiment may comprise digging one or more trenches on the area where upper metal interconnects do not exist, placing a KGD in the trench or trenches, and pouring spin on glass (SOG) to fix the position of the embedded chip.

In one embodiment, multiple IC chips (e.g., LSI chips) can be stacked and/or partially stacked by determining or identifying suitable digging area(s) in a diced chip, strategically forming one or more trenches in the identified area(s), and placing or stacking one or more chips in the one or more trenches thus formed. Trench formation and chip placement need not be repeated on the same area.

In one embodiment, the connection between partially stacked LSI chips can be formed by metal interconnect.

In one embodiment, the connection between LSI chips can be fabricated utilizing conventional wafer fabrication processes, such as Reactive Ion Etching (RIE) and metallic material filling.

One advantage of the invention is that the feature size of the wiring connection can be significantly smaller than those done by wire bonding. Other advantages of the invention include the increased number of connections between LSI chips and the shortened connection path, both of which can facilitate high performance. Moreover, by selectively using the KGD, embodiments of the invention can improve yield and avoid the typical drawbacks of the aforementioned prior techniques.

Other objects and advantages of the present invention will become apparent to one skilled in the art upon reading and understanding the detailed description of the preferred embodiments described herein with reference to the following drawings.

### BRIEF DESCRIPTION OF THE DRAWINGS

A more complete understanding of the present invention and the advantages thereof may be acquired by referring to the following description, taken in conjunction with the accompanying drawings in which like reference numbers indicate like features and wherein:

FIG. 1 is a cross sectional view of a conventional stacked semiconductor device.

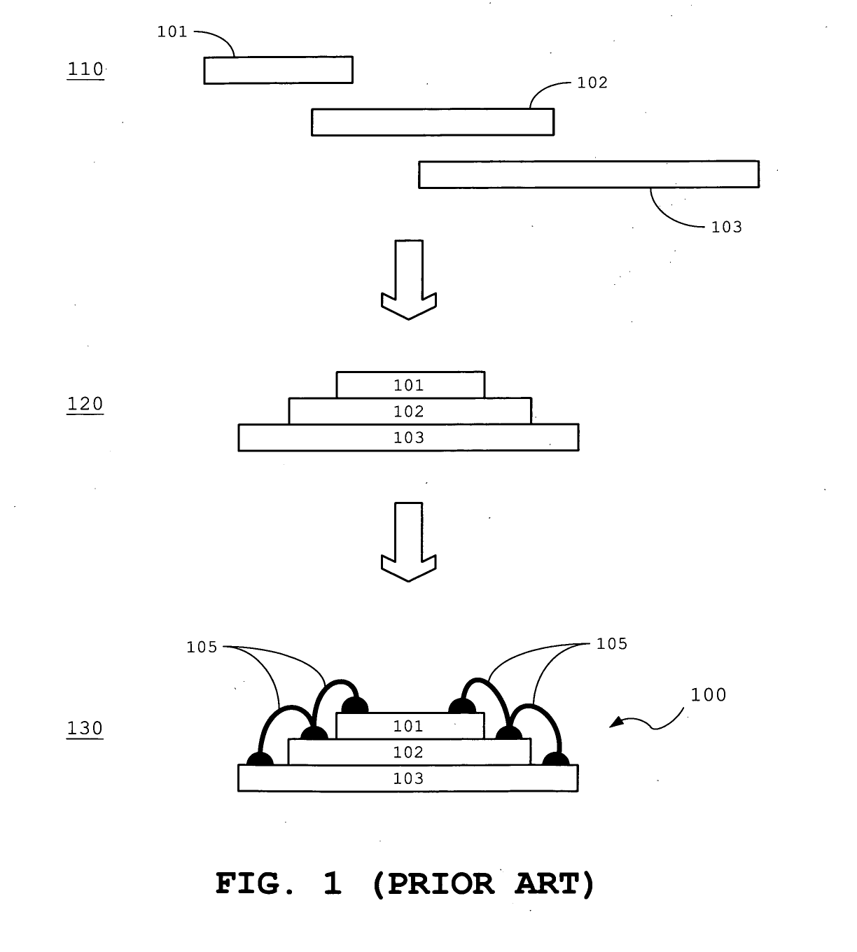

FIG. 2 is a cross sectional view of another conventional stacked semiconductor device.

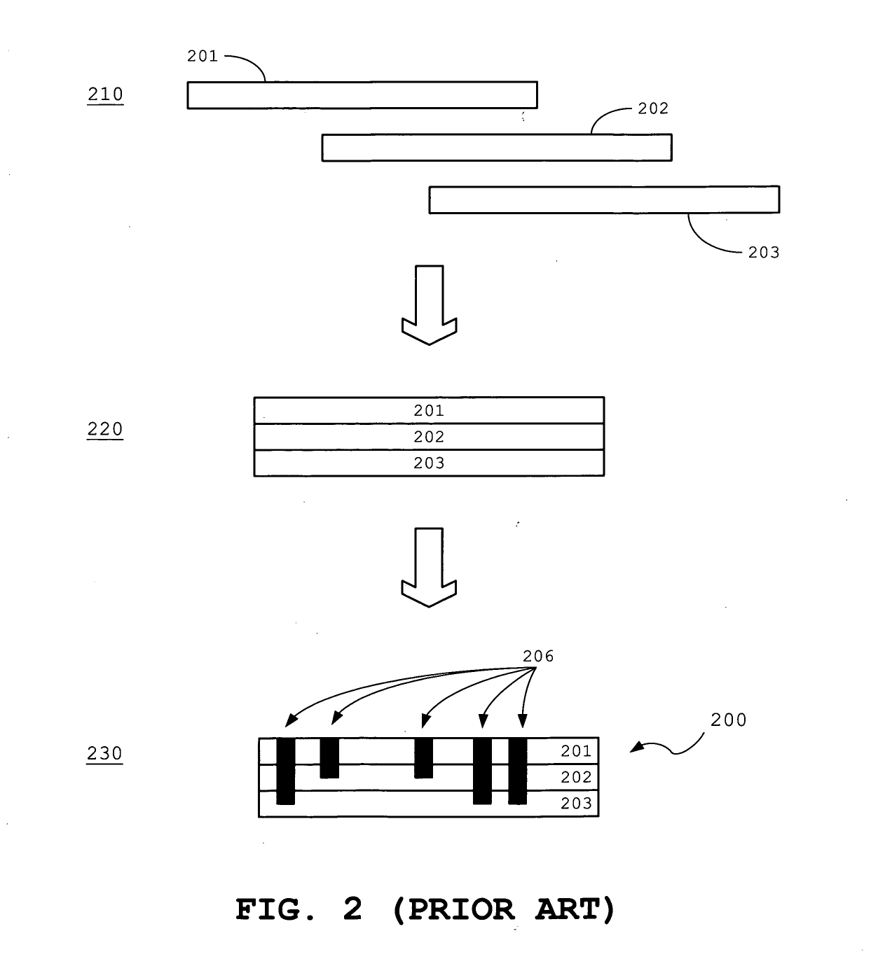

FIG. 3 is a cross sectional view of a schematic representation of a partially stacked semiconductor device according to one embodiment of the invention.

### DETAILED DESCRIPTION

The present invention and various features and advantageous details thereof will now be described with reference to the exemplary, and therefore non-limiting, embodiments that are illustrated in the accompanying drawings. Descriptions of known techniques and technologies may be omitted so as not to unnecessarily obscure the invention in detail. It should be understood, however, that the detailed description and the specific examples, while indicating preferred embodiments of the invention, are given by way of illustration only and not by way of limitation. Figures are not drawn to scale. Various substitutions, modifications, additions and/or rearrangements within the spirit and/or scope of the underlying inventive concept will become apparent to those skilled in the art from this disclosure.

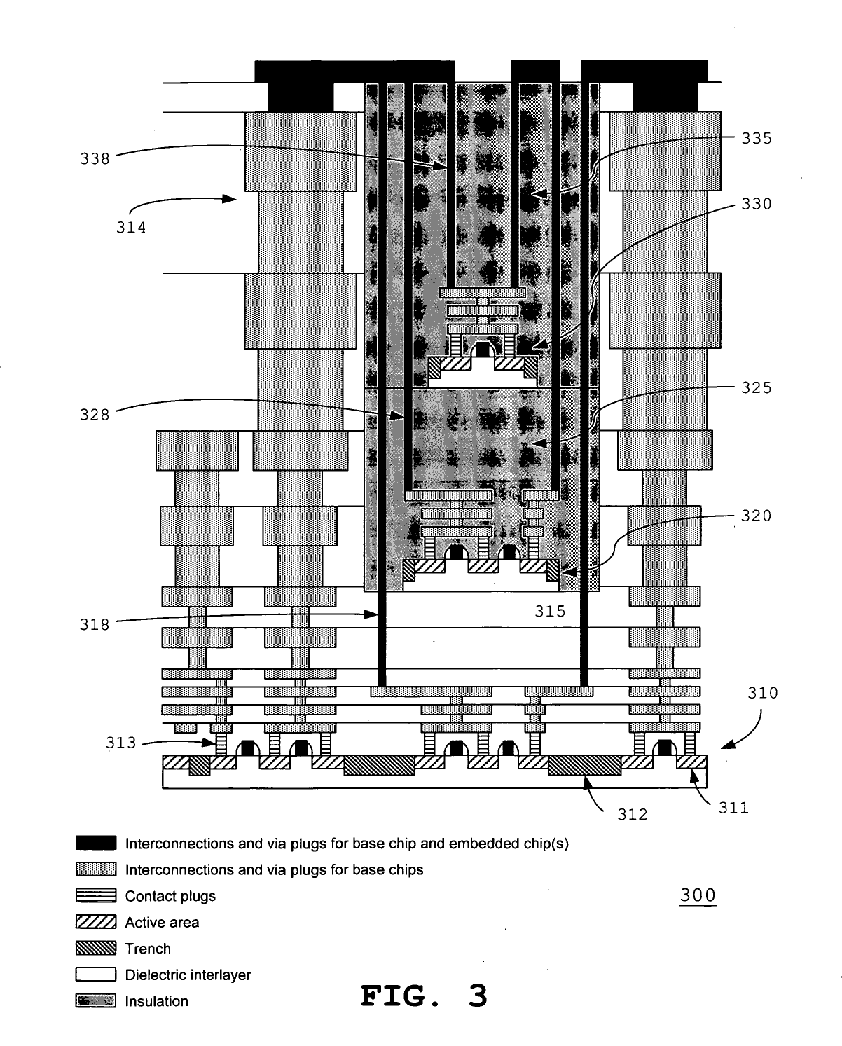

FIG. 3 is a cross sectional view of a schematic representation of a partially stacked semiconductor device 300 according to one embodiment of the invention. In this example, partially stacked semiconductor device 300 comprises a diced base chip 310 having active areas 311 (i.e., the source and drain region of a transistor), shallow trenches 312 isolating active areas 311, contact plugs 313, interconnections and via plugs 314, and layers 315. Layers 315 comprise 10 dielectric interlayers connected by metal interconnections and via plugs 314.

According to embodiments of the invention, one or more LSI chips can be selective buried or embedded in another LSI chip, thus forming a partially stacked final product. Chips to be buried in a base chip are known good dies (KGD) and use only a few (e.g., three or four) metal interconnect layers. As an example, in FIG. 3, base chip 310 embeds two other chips 320 and 330 in a trench formed through several layers of layers 315. Chip 310 could be a high performance LSI chip having about 10 metal interconnect layers and chips 320 and 330 could be other types of LSI chips (e.g., memories) that use only a few lower metal interconnect layers. For example, static random access memory (SRAM) and dynamic RAM (DRAM) chips typically use only the first three or four metal interconnect layers.

In one embodiment, a method of making a partially stacked semiconductor device may comprise determining or identifying at least one suitable area in a diced base chip, strategically digging, etching, or otherwise forming one or more trenches in the identified area(s) where upper metal interconnects do not exist, placing a selected good chip (KGD) in the trench or trenches thus formed, and pouring or otherwise applying a coating insulator material to fix the position of the embedded chip. The trench or trenches can be formed utilizing a conventional wafer fabrication process (e.g., reactive ion etching process). The coating insulator material and corresponding application technique may vary. For example, the coating insulator material may comprise polyimide, organic resin, or a silicon-based mixture (e.g., spin on glass (SOG), which may comprise SiO₂ and dopants known to those skilled in the art). The coating insulator material may be applied by spin-coating.

Optionally, the latter two steps may be repeated if a space is still available in the trench above the embedded chip.

For example, in FIG. 3, the coating insulator material would fill space 325 for chip 320 and space 335 for chip 330.

After the embedded chip(s) are fixed, through holes (e.g., 318, 328, 338) can be dug and filled to form or create metal interconnections and via plugs for the base chip and the embedded chip(s). The connection between LSI chips can be fabricated utilizing a conventional wafer fabrication process.

Embodiments of the present invention can provide many advantages. One advantage is that the feature size of the wiring connection can be significantly smaller than those done by conventional wire bonding. Other advantages of the invention include the increased number of connections between LSI chips and the shortened connection path, both of which can enhance performance. By utilizing unused areas during fabrication, embodiments of the invention can increase area efficiency on LSI chips. Moreover, by selectively using known good chips, embodiments of the invention can improve yield without the drawbacks of conventional techniques. Embodiments of the invention can be particularly useful in system-on-the-chip (SOC) large scale integration.

Although the present invention has been described in detail herein with reference to the illustrative embodiments, it should be understood that the description is by way of example only and is not to be construed in a limiting sense. It is to be further understood, therefore, that numerous changes in the details of the embodiments of this invention and additional embodiments of this invention will be apparent to, and may be made by, persons of ordinary skill in the art having reference to this description. Accordingly, the scope of the invention should be determined by the following claims and their legal equivalents.

What is claimed is:

1. A method of making a partially stacked semiconductor device, comprising the steps of:
forming at least one trench in an area on a base chip, wherein said base chip has a plurality of metal layers and wherein upper metal interconnects do not exist in said area of said base chip;
placing a first known good die (KGD) in said at least one trench; and
applying a coating insulator material to fix said first KGD onto said base chip.

2. The method of claim 1, wherein said coating insulator material comprises polyimide, an organic resin, or a silicon-based mixture.

3. The method of claim 2, wherein said applying step comprises spin-coating said polyimide, said organic resin, or said silicon-based mixture to fix said first KGD onto said base chip.

4. The method of claim 2, wherein said silicon-based mixture is characterized as spin on glass (SOG).

5. The method of claim 4, wherein said applying step comprises spin-coating said SOG to fix said first KGD onto said base chip.

6. The method of claim 1, further comprising:
placing a second KGD above said first KGD in said at least one trench; and
applying said coating insulator material to fix said second KGD onto said base chip.

7. The method of claim 6, further comprising making through holes connecting said base chip, said first KGD, and said second KGD.

8. A partially stacked semiconductor device made according to the method of claim 7.

9. The method of claim 1, further comprising making through holes connecting said base chip and said first KGD.

10. A partially stacked semiconductor device made according to the method of claim 1.

11. A partially stacked semiconductor device, comprising:
a base chip comprising a plurality of metal interconnect layers; and
at least one embedded chip positioned in a trench formed in an area on said base chip where upper metal interconnects do not exist.

12. The partially stacked semiconductor device of claim 11, further comprising one or more interconnections and via plugs connecting said base chip and said at least one embedded chip.

13. The partially stacked semiconductor device of claim 11, wherein said base chip is a large scale integration (LSI) chip having about 10 metal interconnect layers and wherein said at least one embedded chip is a LSI chip that uses first three or four lower metal interconnect layers.

14. The partially stacked semiconductor device of claim 11, wherein said at least one embedded chip is a known good die.

15. The partially stacked semiconductor device of claim 11, wherein said at least one embedded chip is a memory chip.

16. The partially stacked semiconductor device of claim 11, wherein said at least one embedded chip implements a static or dynamic random access memory.

17. The partially stacked semiconductor device of claim 11, further comprising a coating insulator material burying said at least one embedded chip in said trench of said base chip.

18. The partially stacked semiconductor device of claim 17, wherein said coating insulator material comprises polyimide.

19. The partially stacked semiconductor device of claim 17, wherein said coating insulator material comprises a silicon-based mixture.

20. The partially stacked semiconductor device of claim 19, wherein said silicon-based mixture is characterized as spin on glass (SOG).
